(19) United States
(12) Patent Application Publication
(10) Pub. No.: US 2023/0326790 A1
(43) Pub. Date: Oct. 12, 2023

(54) LOW RESISTIVITY CONTACTS AND INTERCONNECTS

(71) Applicant: Lam Research Corporation, Fremont, CA (US)

(72) Inventors: Raihan M. TARAFDAR, Santa Clara, CA (US); Chiukin Steven LAI, Sunnyvale, CA (US); Jeong-Seok NA, San Jose, CA (US)

(73) Assignee: Lam Research Corporation, Fremont, CA (US)

(21) Appl. No.: 17/999,255

(22) PCT Filed: May 21, 2021
(86) PCT No.: PCT/US2021/033564

§ 371 Date: Nov. 18, 2022

Related U.S. Application Data
(60) Provisional application No. 62/704,694, filed on May 22, 2020.

(51) Int. Cl. H01L 21/768; H01L 23/532

(52) U.S. Cl. CPC H01L 21/76877; H01L 21/76814; H01L 21/76876; H01L 23/53266

(57) ABSTRACT

Methods of filling features including metal and dielectric surfaces with conductive materials involve cleaning the metal surfaces with little or no damage to the dielectric surfaces. After cleaning, the feature may be exposed to one or more reactants to fill the feature with the conductive material in an atomic layer deposition (ALD) or chemical vapor deposition (CVD) process. Deposition may be selective or non-selective to the metal surface. In some embodiments, the filled feature is barrier-less, such that the conductive material directly contacts the metal and dielectric surfaces with no interposing barrier or adhesion layer.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Deposition of metals is an integral part of many semiconductor fabrication processes. These materials may be used for horizontal interconnects, vias between adjacent metal layers, and contacts between metal layers and devices. However, as devices shrink and more complex patterning schemes are utilized in the industry, deposition of low resistivity metal films becomes a challenge.

### SUMMARY

One aspect of the disclosure relates to a method including: providing a feature on a substrate, the feature including a metal surface having a layer of metal oxide formed thereon and a dielectric surface; and exposing the feature to a metal halide to remove the layer of metal oxide from the metal surface.

In some embodiments, the method further includes filling the feature with a conductive material. In some such embodiments, the conductive material directly contacts the metal surface and the dielectric surface without an interposed layer. In some such embodiments, exposing the feature to the metal halide and filling the feature with a conductive material are performed in the same chamber. In some such embodiments, exposing the feature to the metal halide and filling the feature with a conductive material are performed in different stations of the same chamber. In some embodiments, exposing the feature to the metal halide and filling the feature with a conductive material are performed in different chambers.

In some embodiments, filling the feature with a conductive material includes depositing a nucleation layer of the conductive material prior to depositing bulk conductive material. In some embodiments, filling the feature with a conductive material includes depositing bulk conductive material without depositing a nucleation layer.

In some embodiments, filling the feature includes atomic layer deposition or chemical vapor deposition process, including plasma enhanced or thermal processes, to deposit bulk conductive material.

In some such embodiments, deposition of the bulk conductive material is selective to the metal surface with respect to the dielectric surface.

In some such embodiments, deposition of the bulk conductive material is non-selective to the metal and dielectric surfaces. According to various embodiments, the conductive material may be selected from molybdenum (Mo), ruthenium (Ru), tungsten (W), iridium (Ir), chromium (Cr), cobalt (Co), and titanium nitride (TiN).

In some embodiments, the metal surface is a one of a titanium nitride (TiN) surface, a molybdenum nitride (MoNₓ) surface, a tungsten nitride (WN) surface, a tungsten carbon nitride (WCₓN_{y}) surface, a tungsten carbide (WCx) surface, a titanium aluminum carbide (TiAlₓC_{y}) surface, or a tantalum nitride (TaN) surface.

In some embodiments, the metal of the metal halide is one of: Mo, W, Cr, Ti, Ta, and vanadium (V).

In some embodiments, the metal halide is one of tungsten hexafluoride (WF6), tungsten hexachloride (WCl6), tungsten pentachloride (WCl5), tungsten hexabromide (WBr6).

In some embodiments, the metal halide is one of molybdenum hexafluoride (MoF6) and molybdenum pentachloride (MoCl5).

In some embodiments, the metal halide is one of niobium pentachloride (NbCl5) and niobium pentabromide (NbBr5).

In some embodiments, the metal halide is one of tantalum pentafluoride (TaF5) and tantalum pentachloride (TaCl5).

In some embodiments, the metal halide is one of vanadium pentafluoride (VF5), chromium pentafluoride (CrF5), and titanium tetrachloride (TiCl4).

In some embodiments, the method further involves performing a reducing treatment to remove residual halogen after removing the layer of metal oxide.

These and other aspects of the disclosure are discussed further below with reference to the drawings.

### BRIEF DESCRIPTION OF DRAWINGS

FIG. 1 depicts an example of a feature according to various embodiments.

FIG. 2 shows example embodiments of patterned features in which deposition of a conductive material may be performed.

FIG. 3 is a flow diagram showing an example of a deposition method to fill a feature with a conductive material.

FIG. 4 show examples of cross-sectional schematic diagrams of patterned features after certain operations of embodiments of the method of FIG. 3.

FIG. 5A shows a comparison of oxygen content at a cobalt (Co)/molybdenum (Mo) interface with and without a tungsten hexafluoride (WF6) treatment prior to ALD deposition of Mo on a Co surface on which Co oxide had formed.

FIG. 5B shows clean of a titanium nitride (TiN) surface using molybdenum pentachloride (MoCl₅).

FIG. 6 depicts a schematic illustration of an embodiment of a process station that may be used for various operations.

FIG. 7 shows an example of a processing system including multiple chambers.

### DETAILED DESCRIPTION

Provided are methods of filling features including metal and dielectric surfaces with conductive materials. The methods involve cleaning the metal surfaces with little or no damage to the dielectric surfaces. After cleaning, the feature may be exposed to one or more reactants to fill the feature with the conductive material in an atomic layer deposition (ALD) or chemical vapor deposition (CVD) process. Deposition may be selective or non-selective to the metal surface. In some embodiments, the filled feature is barrier-less, such that the conductive material directly contacts the metal and dielectric surfaces with no interposing barrier or adhesion layer.

Also provided are methods of cleaning metal surfaces of features including metal and dielectric surfaces. The methods may be performed prior to deposition of a conductive material in the feature. In some embodiments, the filled feature is barrier-less, such that the conductive material directly contacts the metal and dielectric surfaces with no interposing barrier or adhesion layer.

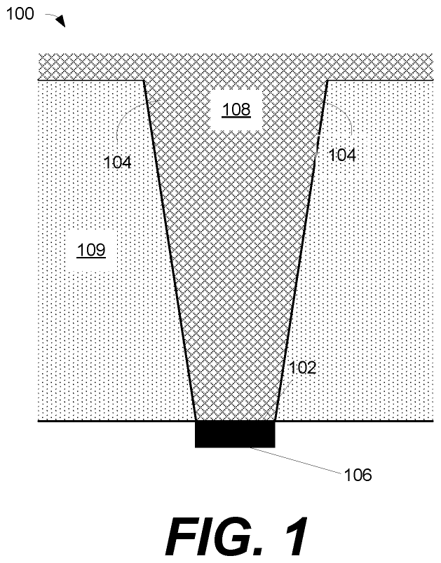

FIG. 1 depicts an example of a feature 100 according to various embodiments. The feature 100 includes a bottom surface 102 and one or more sidewall surfaces 104. The bottom surface 102 is a metal surface of a metal contact 106. The feature 100 is filled with a conductive material to form an interconnect 108 that provides an electrical connection to the underlying metal contact 106.

The metal contact 106 and its surface (bottom surface 102) may be any appropriate metal, such as cobalt (Co), ruthenium (Ru), copper (Cu), tungsten (W), molybdenum (Mo), nickel (Ni), iridium (Ir), rhodium (Rh), tantalum (Ta), and titanium (Ti). In some embodiments, the metal surface 102 is an elemental metal surface. In some embodiments, the metal contact 106 and its surface (bottom surface 102) can be a metal compound such a titanium nitride (TiN) surface, molybdenum nitride (MoNₓ), tungsten nitride (WN), tungsten carbon nitride (WCₓN_{y}), tungsten carbide (WCx), a titanium aluminum carbide (TiAlₓC_{y}) or tantalum nitride (TaN) surface. These surfaces may exhibit deposition selectivity with respect to dielectric oxides. The bottom surface 102 is a part of an underlying metal contact 106 in the example of FIG. 1. It may be part of a main conductor of an underlying layer and not a thin layer such as barrier or adhesion layer.

The one or more sidewall surfaces 104 are dielectric surfaces. Such surfaces include alkoxides such as poly(2-ethyl-2-oxazoline) (PEOX) and silicon-based oxides including tetraethyl orthosilicate (TEOS) oxide, flowable silicon-based oxides, carbon doped silicon-based oxides, etc. In some embodiments, these surfaces are part of the main dielectric layer 109 surrounding the feature. In some embodiments, the sidewall surfaces may be nitrides (e.g., SiₓN_{y}) rather than oxides. The nitrides may be silicon-based nitrides or silicon-based oxynitrides.

The interconnect 108 may be Mo, Ru, W, Ir, chromium (Cr), Co, TiN, and other transition metals or compounds of transition metals. The interconnect 108 directly contacts the dielectric material of the one or more sidewall surfaces 104 and the metal surface of the metal contact 106. In the example of FIG. 1, there are no barrier layers or adhesion layers disposed between the interconnect 108 and metal contact 106 and the interconnect 108 and metal contact 106. While materials such as TiN/Ti are common barrier/adhesion layers in interconnect structures, in the embodiment described with respect to FIG. 1, if used, TiN or other metal nitride is the main conductor of the metal contact and not a barrier layer.

The interconnect 108 may be part of any appropriate part of a partially fabricated semiconductor device, including a source/drain (S/D) connection, a middle of the line (MOL) structure or a back end of line (BEOL) structure. Further, although it is referred to as an interconnect, it may include any conductive film embedded within dielectric, such as a metal line and the like.

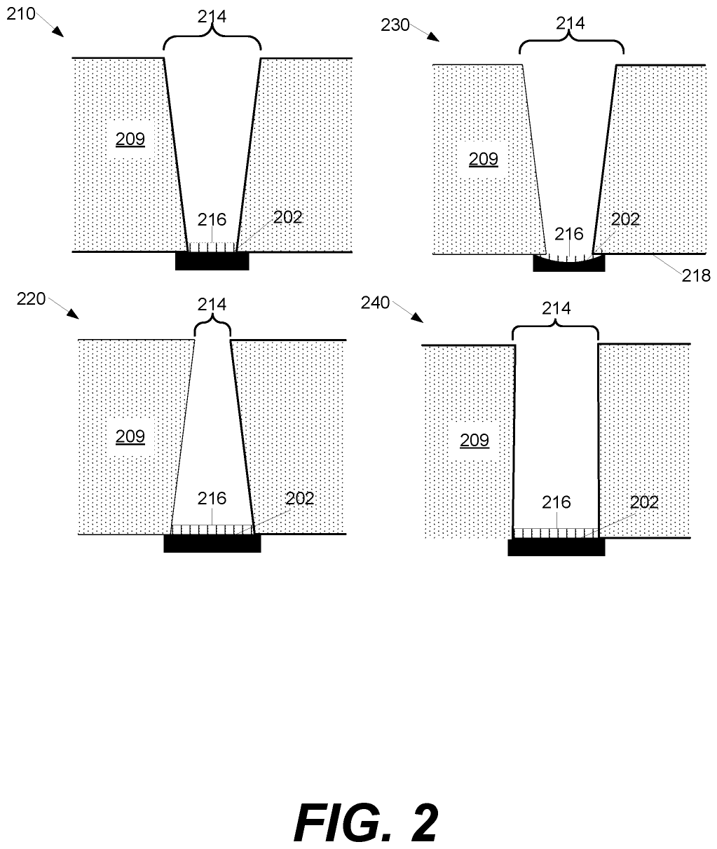

FIG. 2 shows example embodiments of patterned features in which deposition of a conductive material may be performed. A patterned feature maybe a via or a trench or other appropriate feature formed as a result of a patterning operation in a dielectric layer. Feature 210 shows an example of a patterned feature having an open profile that expands gradually from the bottom of the feature to the feature opening 214.

Feature 220 shows an example of a patterned feature having a re-entrant profile that narrows from the bottom of the feature to the feature opening 214. A re-entrant profile may also include an overhang at the feature opening 214. Feature 230 shows a feature with a metal undercut profile. According to various implementations, the profile has the metal surface 202 below the sidewall base 218 of the feature 230. There may be voids between the bottom surface 202 and the sidewall base 218. In each of the above profiles, the bottom surface 202 is a metal surface as described above. There may be metal oxide 216 formed on bottom surface 202. Feature 240 shows an example of a patterned feature having substantially vertical sidewalls. The metal oxide may be an oxide of an elemental metal (e.g., copper oxide on a Cu surface) or an oxide of a metal compound (e.g., titanium oxynitride on a TiN surface).

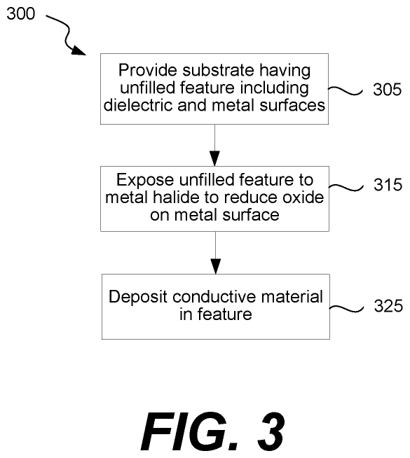

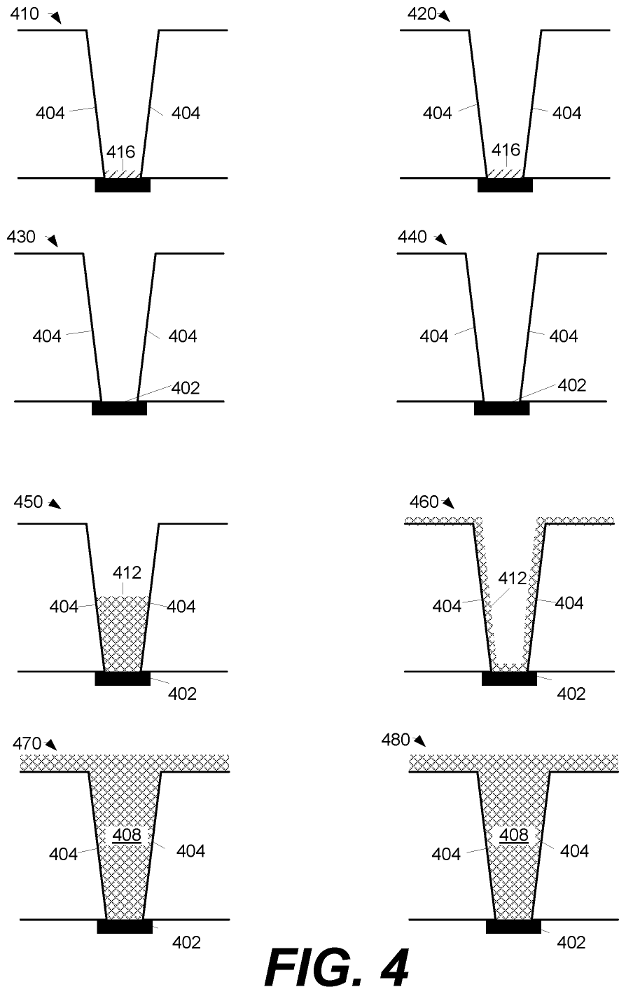

FIG. 3 is a flow diagram showing an example of a deposition method 300 to fill a feature with a conductive material. FIG. 4 show examples of cross-sectional schematic diagrams of patterned features after certain operations of embodiments of the method of FIG. 3. In particular, FIG. 4 shows examples of selective deposition at and non-selective deposition.

In FIG. 3, at operation 305, a substrate including an unfilled feature is provided. As indicated above, the feature may be part of a partially fabricated semiconductor device. The feature includes metal and dielectric surfaces as described above. The metal surface includes metal oxide that may be formed from exposure to air or another oxidative environment. The substrate may be provided to a processing chamber as described further below.

In FIGS. 4, at 410 and 420, patterned features are shown, including bottom surface 402 and sidewall surface 404, and metal oxide 416 formed on the bottom surface.

Turning back to FIG. 3, the substrate is exposed to a metal halide to reduce the oxide in an operation 315. The metal halide is provided as a gas to the chamber housing the substrate and may be pulsed or continuously flowed into the chamber. The metal halide can effectively reduce the oxide on the bottom surface of the feature with little or no damage to the dielectric. This is unlike other halide treatments, which can damage the dielectric. For example, nitrogen trifluoride etches the dielectric, resulting in an increase in the feature critical dimension. The halide compounds are more effective at removing the oxidized layer than other reducing agents such as ammonia or hydrazine.

In some embodiments, the metal halide is pulsed with the pulses separated by an inert purge gas. Examples of inert purge gas include argon (Ar). This can avoid saturation by continuous flow.

The metal halide is any that is volatile or has sufficient vapor pressure to be delivered to the substrate at or below the substrate temperature. Example substrate temperatures during operation 315 range from 100° C. to 450° C. For some metal halides, higher temperatures may result in dielectric etch. The metal halide may contain any appropriate metal including Mo, W, Cr, Ti, Ta, and vanadium (V), and any halide including fluorine (F), chlorine (Cl), bromine (Br), and iodine (I). Examples of tungsten halides that may be used include tungsten hexafluoride (WF₆), tungsten hexachloride (WCl₆), tungsten pentachloride (WCl₅), and tungsten hexabromide (WBr₆). Examples of molybdenum halides that may be used include molybdenum hexafluoride (MoF₆) and molybdenum pentachloride (MoCl₅). Examples of niobium halides that may be used include niobium pentachloride (NbCl₅), niobium tetraiodide (NbI₄), and niobium pentabromide (NbBr₅). Examples of tantalum halides that may be used include tantalum pentafluoride (TaF₅), tantalum pentaiodide (TaI₅), and tantalum pentachloride (TaCl₅). Examples of vanadium halides that may be used include vanadium pentafluoride (VF₅). Examples of chromium halides that may be used include chromium pentafluoride (CrF₅) and chromium diiodide (CrI₂). Examples of titanium halides that may be used include titanium tetrachloride (TiCl₄).

The metal halide may be mixed with an inert gas such as argon (Ar), helium (He), and the like. This may be used to dilute the metal halide and control the reduction rate. Examples of chamber pressures during operation 315 range from 1 to 30 Torr. Treatment time may range from 2 seconds to 4 minutes, or 2 seconds to 60 seconds. In some embodiments, treatment time may be around 2 minutes to 3 minutes. In some embodiment, pulses of between 1 and 60 seconds, or 1 and 10 seconds, are used.

It is understood that exposure to a particular metal halide may include exposure to other halides that form in the gas source, gas inlet, and/or chamber. For example, WBr₆ may decompose to tungsten pentabromide (WBr₅) and tungsten tetrabromide (WBr₄) and WF₆ to tungsten pentafluoride (WF₅) and tungsten tetrafluoride (WF₄). A metal halide may take various forms including dimers and other oligomers; for example, MoCl₅ forms a dimer Mo₂Cl₁₀. The metal halides may be oxygen-free. (Some metal oxy-halides, molybdenum tetrachloride oxide (MoOCl₄) can etch/reduce the metal oxide, however, they generally are less effective than the metal halides. Other metal oxy-halides are listed below with reference to the ALD or CVD deposition.) Selection of a particular metal halide depends on the etch selectivity of the metal oxide to the silicon oxide or other dielectric material.

In FIGS. 4, at 430 and 440, patterned features are shown, including bottom surface 402 and sidewall surface 404, with metal oxide now removed from the bottom surface and ready for deposition. In some embodiments, some of the contact itself may be removed, either incidentally in removing the metal oxide or intentionally, e.g., to increase aspect ratio. Example amounts of etched material can range from 5 to 6 Angstroms to remove oxide only, or up to 20 Angstroms or more Angstroms to remove underlying contact.

At 325, conductive material is deposited into the features. As indicated above, this is done without a barrier or adhesion layer. Operation 325 may involve any of an ALD, CVD, or PVD process. ALD and CVD processes may be plasma enhanced (PEALD or PECVD) or thermal ALD or CVD processes. The feature includes both dielectric and metal surfaces and the deposition may be selective or non-selective to the metal surface. Selectivity can depend on the particular precursor and reaction conditions, with examples provided in the description further below.

In FIG. 4, at 450, a patterned feature during selective deposition is shown. The fill is bottom-up, with little or no deposition on the sidewalls. In some embodiments, some amount of material may deposit on the sidewalls. At 460, a patterned feature during non-selective deposition is shown. The fill is conformal. The filled features are shown at 470 and 480.

As described further below, in other embodiments, other methods such as sputtering and other physical vapor deposition (PVD) or plating processes may be used to deposit metal after a metal halide reducing operation. Deposition of the conductive material is a bulk deposition process and may or may not include deposition of a nucleation layer prior to the bulk deposition.

Operations 315 and 325 may be performed in the same chamber or in different chambers, which may or may not be integrated under a common vacuum. In some embodiments, they are performed in different stations of a multi-station chamber.

As indicated above, in some embodiments, operation 325 includes deposition of a bulk conductive material by CVD or ALD. In the context of this description, CVD refers to processes in which reactants exist in vapor phase in the reactor at the same time, and are generally introduced at the same time, while ALD refers to processes that introduces reactants in sequential pulses, typically separated by purges. Example reactants and reaction conditions that may be used for ALD and/or CVD reactions to fill a feature with the conductive material are given below.

In some embodiments, the feature surfaces may be susceptible to incorporation of halogen from the metal halide during operation 315. Operation 325 may use relatively high temperatures to help desorb or otherwise remove any incorporated halogen. In some embodiments, exposure to a reducing gas like H₂ at relatively high temperatures may be used to remove residual halogen. Such an operation may take place between operations 315 and 325.

In some implementations, the methods described herein involve deposition of a nucleation layer prior to deposition of the bulk conductive layer. A nucleation layer is typically a thin conformal layer that facilitates subsequent deposition of bulk conductive material thereon. In certain implementations, the nucleation layer is deposited using ALD techniques. Nucleation layer thickness can depend on the nucleation layer deposition method as well as the desired quality of bulk deposition. In general, nucleation layer thickness is sufficient to support high quality, uniform bulk deposition. As nucleation layers have higher resistivity than bulk layers, they are generally no thicker than this. Examples may range from 10Å-100Å. In certain embodiments, bulk conductive material may be deposited directly in the feature without use of a nucleation layer. The bulk conductive material may be deposited by ALD or CVD. Grain size is larger and resistivity less than the nucleation layer.

In CVD or ALD processes, a metal-containing precursor may be reacted with a reducing agent or other reactant to form a metal or metal compound material.

Examples of W-containing precursors for ALD and CVD of tungsten or tungsten-containing materials include WF₆, WCl₆, WCl₅, and tungsten hexacarbonyl (W(CO)₆). In some embodiments, tungsten oxy-halides including WO₂Cl₂, WOBr₄, WOCl₄, and WOF₄ may be used. Organo-metallic precursors such as MDNOW (methylcyclopentadienyl-dicarbonylnitrosyl-tungsten) and EDNOW (ethylcyclopentadienyl-dicarbonylnitrosyl-tungsten) may also be used. In some embodiments, a nitrogen-containing tungsten-containing organo-metallic precursor such as bis(tert-butylimino) bis(dimethylamino) tungsten (W[N(C₄H₉)]₂[N(CH₃)₂]₂ may be used to deposit tungsten or tungsten nitride films.

Examples of Mo-containing precursors for ALD or CVD of molybdenum or molybdenum-containing materials include MoF₆, MoCl₅, molybdenum dichloride dioxide (MoO₂Cl₂), molybdenum tetrachloride oxide (MoOCl₄), and molybdenum hexacarbonyl (Mo(CO)₆). Other Mo oxyhalides of the formula MoₓOₓH_{z} and H is a halogen (fluorine (F), chlorine (Cl), bromine (Br), or iodine (I)) and x, y, and z being any number greater than zero that can form a stable molecule. These include molybdenum tetrafluoride oxide (MoOF₄), molybdenum dibromide dioxide (MoO₂Br₂), and molybdenum oxyiodides MoO₂I and Mo₄O₁₁I. Organo-metallic precursors may also be used with examples including Mo precursors having cyclopentadienyl ligands. Further examples include precursors of the formula Mo₂Lₙ, wherein each L is independently selected from an amidate ligand, an amidinate ligand, and a guanidinate ligand, where n is 2-5. The Mo₂Lₙ, precursor includes a multiple molybdenum-molybdenum bond (such as a double bond or any multiple bond with a bond order of 2-5). Further examples include halide-containing heteroleptic molybdenum compounds (i.e., compounds having different types of ligands). Particular examples of such precursors are compounds that include molybdenum, at least one halide forming a bond with molybdenum, and at least one organic ligand having any of the N, O, and S elements, where an atom of any of these elements forms a bond with molybdenum. Examples of suitable organic ligands that provide nitrogen or oxygen bonding include amidinates, amidates, iminopyrrolidinates, diazadienes, beta-imino amides, alpha-imino alkoxides, beta-amino alkoxides, beta-diketiminates, beta-ketoiminates, beta-diketonates, amines, and pyrazolates. Examples of suitable organic ligands that provide sulfur bonding include thioethers, thiolates, dithiolenes, dithiolates, and a-imino thiolenes. These ligands may be substituted or unsubstituted. In some embodiments, these ligands include one or more substituents independently selected from the group consisting of H, alkyl, fluoroalkyl, alkylsilyl, alkylamino, and alkoxy substituents. The organic ligands can be neutral or anionic (e.g., monoanionic or dianionic), and molybdenum can be in a variety of oxidation states, such as +1, +2, +3, +4, +5, and +6.

Examples of Ru-containing precursors for ALD or CVD or ruthenium or ruthenium-containing include (ethylbenzyl)(1-ethyl-1,4-cyclohexadienyl)Ru(0), (1-isopropyl-4-methylbenzyl)(1,3-cyclohexadienyl)Ru(0), 2,3-dimethyl-1,3-butadienyl)Ru(0)tricarbonyl, (1,3-cyclohexadienyl)Ru(0)tricarbonyl, and (cyclopentadienyl)(ethyl)Ru(II)dicarbonyl, which may be used for oxidative reactions. Examples of ruthenium precursors that react with non-oxidizing reactants include bis(5-methyl-2,4-hexanediketonato)Ru(II)dicarbonyl and bis(ethylcyclopentadienyl)Ru(II). Additional examples of ruthenium precursors include Ru₃(CO)₁₂, (2,4-Dimethylpentadienyl) (ethylcyclopentadienyl)ruthenium, tricarbonyl(h4-cyclohexa-1,3-diene)ruthenium and similar analogs, and (η4-2,3-dimethylbutadiene)(tricarbonyl)ruthenium.

Examples of Co-containing precursors for ALD or CVD of cobalt or cobalt-containing materials include tris(2,2,6,6-tetramethyl-3,5-heptanedionato)cobalt, bis(cyclopentadienyl)cobalt,dicobalt hexacarbonyl butylacetylene, dicarbonyl cyclopentadienyl cobalt (I), cobalt carbonyl, various cobalt amidinate precursors, cobalt diazadienyl complexes, cobalt amidinate/guanidinate precursors, and combinations thereof. Examples of Ti-containing precursors for ALD or CVD include TiCl₄ and tetrakis(dimethylamino)titanium (TDMAT). Examples of Ta-containing precursors for ALD or CVD of tantalum or tantalum-containing materials include TaF₅ and pentakis-dimethylamino tantalum (PDMAT).

Examples of reducing agents can include hydrogen (H₂), boron-containing reducing agents including diborane (B₂H₆) and other boranes, silicon-containing reducing agents including silane (SiH₄) and other silanes, hydrazines, and germanes. In some implementations, pulses of metal-containing precursors can be alternated with pulses of one or more reducing agents, e.g., S/W/S/W/B/W, etc., W represents a tungsten-containing precursor, S represents a silicon-containing precursor, and B represents a boron-containing precursor. In some implementations, a separate reactant may not be used, e.g., a metal-containing precursor may undergo thermal or plasma-assisted decomposition. In some embodiments, H₂ is used as a reducing agent for bulk layer deposition to deposit high purity films.

As described above, the selectivity of the deposition can depend on the material being deposited, precursors, and process conditions. In one example, molybdenum deposited from metal halide precursors grows on oxide surfaces but may be deposited selectively by controlling the Mo-containing precursors, temperature, and reactant partial pressure. Molybdenum oxyhalides may be used to deposit selectively on metal surfaces in operation 325. Temperature affects selectivity, grain size, and resistance. Higher temperatures may reduce selectivity of the Mo film and result in growth on the oxide or nitride of the sidewall surfaces 404 as well as on the metal-containing bottom surface 402. However, if temperatures are too low, the impurity level may be increased and grain size may be reduced, increasing resistance. Substrate temperature may be between 350° C. and 600° C., inclusive, to selectively deposit Mo using a chlorine-containing chemistry. As noted above, selectivity can improve as temperature is lowered. Thus, in some embodiments, substrate temperature may be between about 350° C. and 550° C., or 350° C. and 450° C. for a chlorine-containing precursor. Substrate temperatures for a fluorine-containing chemistry may be lower, e.g., 150° C. to 350° C.

To deposit non-selectively (or less selectively), temperature can be controlled to allow nucleation on the sidewall surfaces and field areas. This may be appropriate once the feature has filled sufficiently such that conformal growth can be used to obtain good feature fill without a risk of voids. The temperature may be at least 500° C. and as high as 800° C. if allowed by the thermal budget in the device structure.

Deposition of pure metal films from oxygen-containing precursors is challenging due to the ease of incorporation of oxygen into the films during the deposition process. If oxygen is incorporated, the resistivity increases. The methods and apparatus described herein may be implemented to deposition pure metal films that have less than 1 atomic percent oxygen in some embodiments. The ratio of the reducing agent to the metal oxy-halide precursor is significantly greater than 1 and the deposited film contains no more than 1 atomic percentage oxygen. Molar ratios of at least 100:1 may be used. In some embodiments, the deposited film has a halogen concentration of no more than 1E18 atoms/cm³. To deposit pure films with no more than one atomic percentage oxygen, the reducing agent to metal precursor ratio is significantly greater than 1, e.g., at least 20:1 or at least 50:1. Examples of temperatures may ranges from 350° C. to 600° C. for chlorine-containing precursors and 150° C. to 500° C. for fluorine-containing precursors. Examples of chamber pressures may range from 1 torr to 100 torr. The reducing agent:precursor ratio used to obtain pure films may be lower as temperature is increased. In some embodiments, the temperature for chlorine-containing precursors is at least 400° C. Higher pressures may also be used to reduce the reducing agent:precursor ratio as the partial pressure of the reducing agent is increased.

As indicated above, in some embodiments, a relatively high deposition temperature (e.g., above 500° C.) may be useful to remove any residual fluorine or other halogen after the metal halide treatment. Accordingly, in some embodiments, the substrate temperature is raised by at least 50° C., 100° C., or 150° C. between operations 315 and 325.

In the above description, a metal surface of a feature including a dielectric surface is exposed to a metal halide. In other embodiments, any metal-containing surface may be exposed to the metal halides described above for removal of oxide formed thereon. For example, a feature such as shown in FIG. 2 may have a thin barrier and/or adhesion layer coating at least the dielectric sidewall surfaces. The metal halide treatment may be used to clean the barrier and/or adhesion layer.

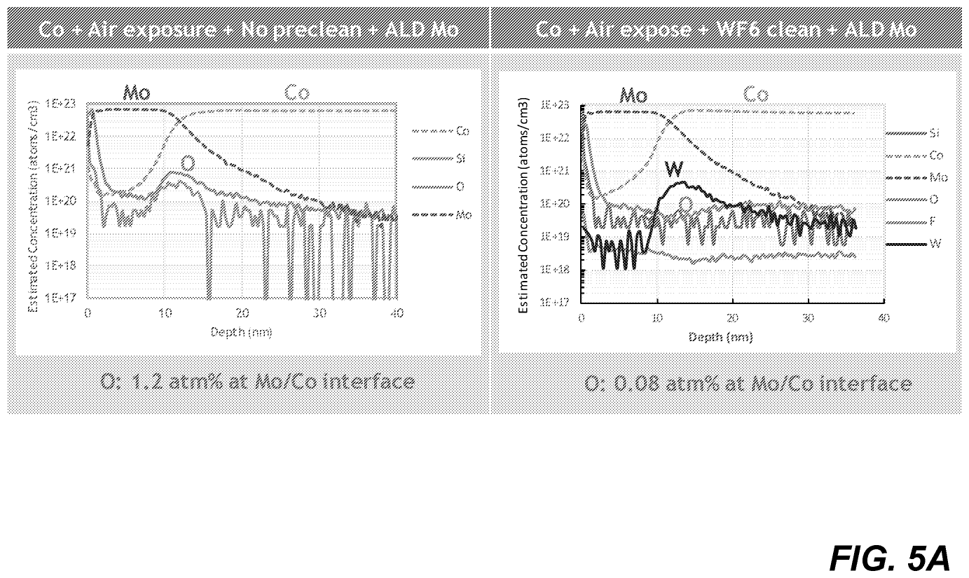

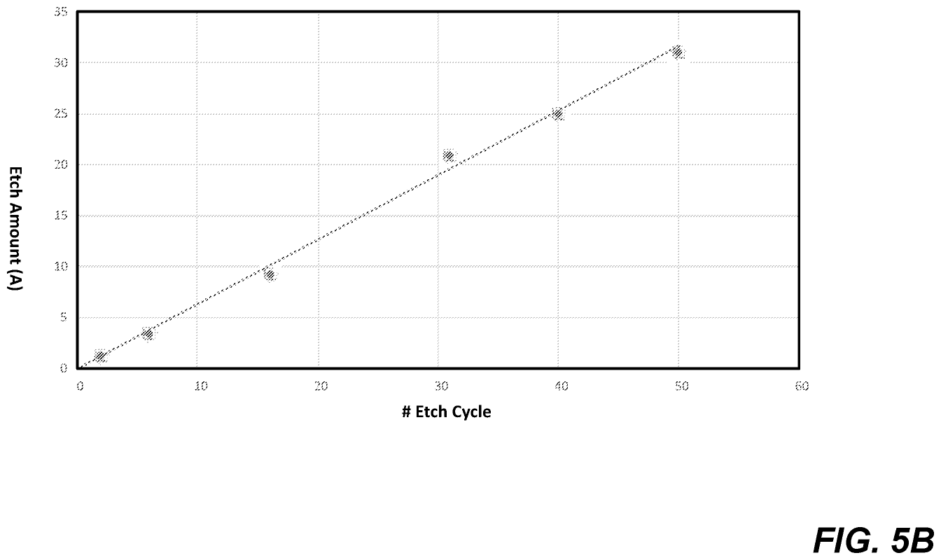

FIG. 5A shows a comparison of oxygen content at a Co/Mo interface with and without a WF6 treatment prior to ALD deposition of Mo on a Co surface on which Co oxide had formed. As can be seen from the graphs, the oxygen content is reduced by an order of magnitude at the interface. According to various embodiments, the residual oxygen at the interface may be equal to or less than 1E20 atoms/cm³.

FIG. 5B shows etching of a TiN surface using pulses of MoCl₅ separated by purges. As can be seen, the amount of material etched is linearly related to the number of pulse/purge cycles, allowing digital control of the amount etched. In the example of FIG. 5B, both titanium oxynitride and underlying titanium nitride were etched.

### Apparatus

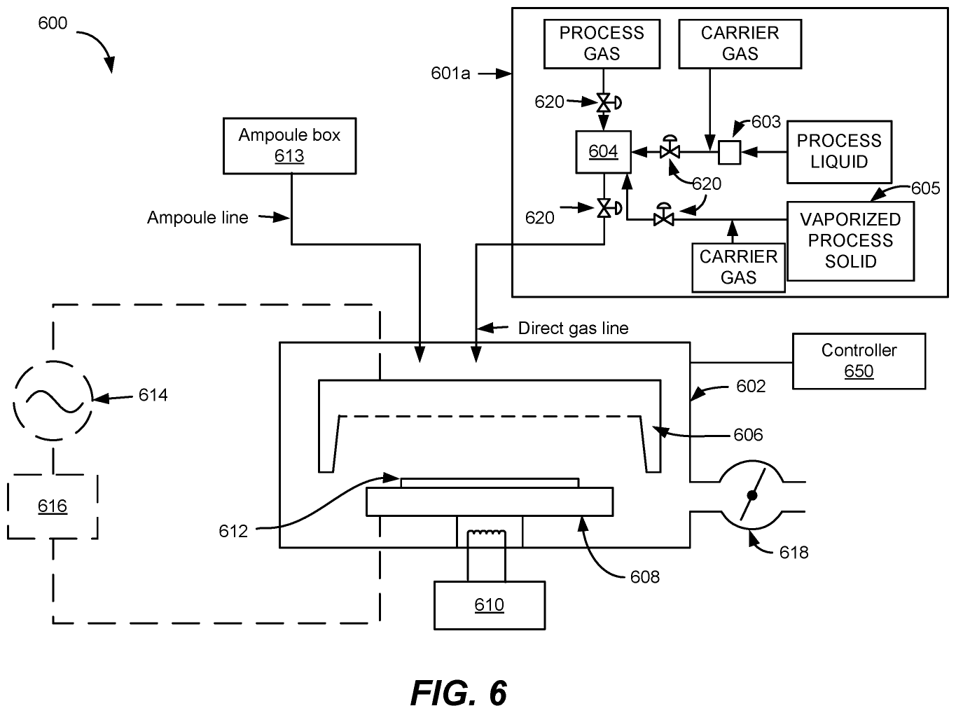

As indicated above, operations 315 and 325 of FIG. 3 may be performed in the same or different chambers and in the same or different stations. FIG. 6 depicts a schematic illustration of an embodiment of a process station 600 that may be used for operation 315 and/or operation 325. The process station 600 fluidly communicates with reactant delivery system 601a for delivering process gases to a distribution showerhead 606. Reactant delivery system 601a includes a mixing vessel 604 for blending and/or conditioning process gases (such as a metal halide gas and an inert gas for a metal halide reducing treatment or a metal precursor-containing gas and hydrogen-containing gas for a deposition) for delivery to showerhead 606. One or more mixing vessel inlet valves 620 may control introduction of process gases to mixing vessel 604.

The embodiment of FIG. 6 includes a vaporization point 605 for process solids to be supplied to the mixing vessel 604. In another scenario, vaporization process solids may be supplied directly to the showerhead 606. The vaporization can be sublimation or from solid to liquid to vapor. With the exception of WF₆ and MoF₆, the metal halides are generally solid at room temperature.

As an example, the embodiment of FIG. 6 includes a vaporization point 603 for vaporizing liquid reactant to be supplied to the mixing vessel 604. In some embodiments, vaporization point 603 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 604. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to showerhead 606.

In some embodiments, a liquid flow controller (LFC) upstream of vaporization point 603 may be provided for controlling a mass flow of liquid for vaporization and delivery to process chamber 602. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 606 distributes process gases toward substrate 612. In the embodiment shown in FIG. 6, the substrate 612 is located beneath showerhead 606 and is shown resting on a pedestal 608. Showerhead 606 may have any suitable shape and may have any suitable number and arrangement of ports for distributing process gases to substrate 612.

In some embodiments, pedestal 608 may be raised or lowered to expose substrate 612 to a volume between the substrate 612 and the showerhead 606. In some embodiments, pedestal 608 may be temperature controlled via heater 610. Pedestal 608 may be set to any suitable temperature, such as between about 150° C. and about 600° C. during operations for performing various disclosed embodiments. It will be appreciated that, in some embodiments, pedestal height may be adjusted programmatically by a suitable computer controller 650. At the conclusion of a process phase, pedestal 608 may be lowered during another substrate transfer phase to allow removal of substrate 612 from pedestal 608.

In some embodiments, a position of showerhead 606 may be adjusted relative to pedestal 608 to vary a volume between the substrate 612 and the showerhead 606. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers 650.

In some embodiments where plasma may be used for PECVD or PEALD, showerhead 606 and pedestal 608 electrically communicate with a radio frequency (RF) power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Likewise, RF power supply 614 may provide RF power of any suitable frequency. In some embodiments, RF power supply 614 may be configured to control high- and low-frequency RF power sources independently of one another. Example low-frequency RF frequencies may include, but are not limited to, frequencies between 0 kHz and 900 kHz. Example high-frequency RF frequencies may include, but are not limited to, frequencies between 1.8 MHz and 2.45 GHz, or greater than about 13.56 MHz, or greater than 27 MHz, or greater than 80 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 650 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of a metal halide gas, instructions for setting a flow rate of a carrier gas (such as argon), and time delay instructions for the first recipe phase. A second, subsequent recipe phase may include instructions for modulating or stopping a flow rate the metal halide gas, and instructions for modulating a flow rate of a carrier or purge gas and time delay instructions for the second recipe phase.

For ALD deposition, a first recipe phase may include instructions for modulating a flow rate of a first reactant gas (e.g., a metal precursor gas), instructions for modulating the flow rate of a carrier or purge gas, and time delay instructions for the first recipe phase. A second, subsequent recipe phase may include instructions for modulating or stopping a flow rate the reactant gas, and instructions for modulating a flow rate of a carrier or purge gas and time delay instructions for the second recipe phase. A third recipe phase may include instructions for modulating second reactant gas such as H₂, instructions for modulating the flow rate of a carrier or purge gas, instructions for igniting a plasma, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for process station 600 may be provided by butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to the process station 600.

As described above, operations 315 and 325 may be performed in a single station of a single or multi-station chamber, in different stations of a multi-station chamber, or in different chambers. If performed in different chambers, they may be integrated under a common vacuum environment to prevent oxidation of the metal after the metal halide treatment and removal of metal oxide. In some embodiments, they may not be integrated with the metal halide treatment providing a passivation effect to prevent oxidation, at least for a relatively short time.

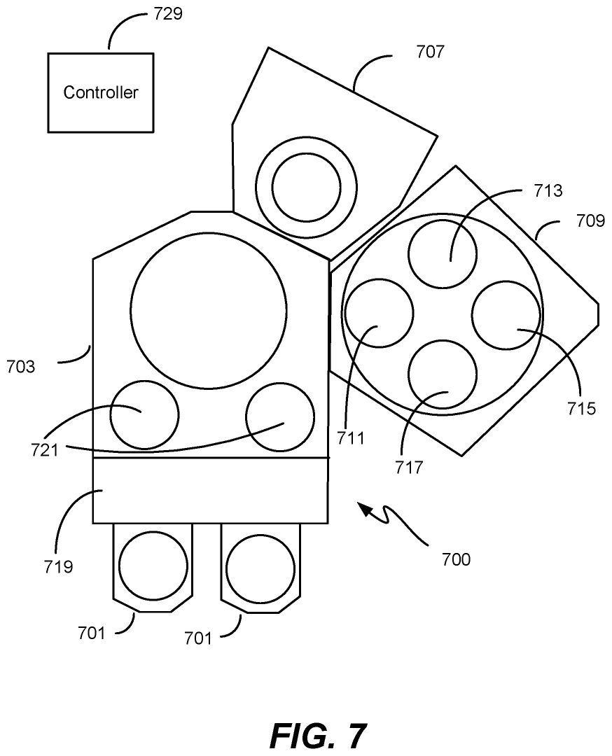

FIG. 7 shows an example of a processing system including multiple chambers. The system 700 includes a transfer module 703. The transfer module 703 provides a clean, vacuum environment to minimize risk of contamination of substrates being processed as they are moved between various reactor modules. Mounted on the transfer module 703 is a multi-station reactor 709 capable of performing ALD and CVD with according to embodiments. In some embodiments, the reactor 709 also performs the metal halide exposure prior to ALD or CVD.

Reactor 709 may include multiple stations 711, 713, 715, and 717 that may sequentially perform operations in accordance with disclosed embodiments. For example, reactor 709 may be configured such that station 711 performs the metal halide reducing treatment described herein, and stations 713 performs nucleation layer deposition by ALD, and stations 715 and 717 perform bulk layer deposition by ALD or CVD. Two or more stations may be included in a multi-station reactor, e.g., 2-6, with the operations appropriately distributed. For example, a two-station reactor may be configured to expose the substrate to a metal halide in a first station followed by conductive material deposition in a second station. As described above with respect to FIG. 6, stations may include a heated pedestal or substrate support, one or more gas inlets or showerhead or dispersion plate.

Also mounted on the transfer module 703 may be one or more single or multi-station modules 707. In some embodiments, the metal halide exposure may be performed in a module 707, after which the substrate is transferred under vacuum to another module (e.g., another module 707 or reactor 709) for deposition of the conductive material. The module 707 may be a preclean module that performs a clean such as Ar sputter clean and/or H₂ plasma clean prior to deposition. In some embodiments, the metal halide exposure is performed in such a preclean module, either before or after the sputter and/or plasma clean.

The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all the activities of the apparatus. The system controller 729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 729 may be employed in some embodiments.

Typically, there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 729. The signals for controlling the process are output on the analog and digital output connections of the deposition apparatus 700.

The system software may be designed or configured in many ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 729 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 729, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 729, in some implementations, may be a part of or coupled to a computer that is integrated with, coupled to the system, otherwise networked to the system, or a combination thereof. For example, the controller 729 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a PVD chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 729 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
providing a feature on a substrate, the feature comprising a metal surface having a layer of metal oxide formed thereon and a dielectric surface; and
exposing the feature to a metal halide to remove the layer of metal oxide from the metal surface.

2. The method of claim 1, further comprising filling the feature with a conductive material.

3. The method of claim 2, wherein the conductive material directly contacts the metal surface and the dielectric surface without an interposed layer.

4. The method of claim 2, wherein filling the feature with a conductive material comprises depositing a nucleation layer of the conductive material prior to depositing bulk conductive material.

5. The method of claim 2, wherein filling the feature with a conductive material comprises depositing bulk conductive material without depositing a nucleation layer.

6. The method of claim 1, wherein filling the feature comprises an atomic layer deposition or chemical vapor deposition process, including plasma enhanced or thermal processes, to deposit bulk conductive material.

7. The method of claim 6, wherein deposition of the bulk conductive material is selective to the metal surface with respect to the dielectric surface.

8. The method of claim 6, wherein deposition of the bulk conductive material is non-selective to the metal and dielectric surfaces.

9. The method of any of claim 2, wherein exposing the feature to the metal halide and filling the feature with a conductive material are performed in the same chamber.

10. The method of claim 2, wherein exposing the feature to the metal halide and filling the feature with a conductive material are performed in different stations of the same chamber.

11. The method of any of claim 2, wherein exposing the feature to the metal halide and filling the feature with a conductive material are performed in different chambers.

12. The method of claim 1, wherein the conductive material is selected from molybdenum (Mo), ruthenium (Ru), tungsten (W), iridium (Ir), chromium (Cr), cobalt (Co), and titanium nitride (TiN).

13. The method of claim 1, wherein the metal surface is a one of a titanium nitride (TiN) surface, a molybdenum nitride (MoNₓ) surface, a tungsten nitride (WN) surface, a tungsten carbon nitride (WCₓN_{y}) surface, a tungsten carbide (WCx) surface, a titanium aluminum carbide (TiAlₓC_{y}) surface, or a tantalum nitride (TaN) surface.

14. The method of claim 1, wherein the metal of the metal halide is one of: Mo, W, Cr, Ti, Ta, and vanadium (V).

15. The method of claim 1, wherein the metal halide is one of tungsten hexafluoride (WF₆), tungsten hexachloride (WCl₆), tungsten pentachloride (WCl₅), tungsten hexabromide (WBr₆).

16. The method of claim 1, wherein the metal halide is one of molybdenum hexafluoride (MoF₆) and molybdenum pentachloride (MoCl₅).

17. The method of claim 1, wherein the metal halide is one of niobium pentachloride (NbCl₅) and niobium pentabromide (NbBr₅).

18. The method of claim 1, wherein the metal halide is one of tantalum pentafluoride (TaF₅) and tantalum pentachloride (TaCl₅).

19. The method of claim 1, wherein the metal halide is one of vanadium pentafluoride (VF₅), chromium pentafluoride (CrF₅), and titanium tetrachloride (TiCl₄).

20. The method of claim 1, further comprising performing a reducing treatment to remove residual halogen after removing the layer of metal oxide.
